(19) United States
(12) Patent Application Publication
(10) Pub. No.: US 2012/0125423 A1
(43) Pub. Date: May 24, 2012

(54) TRANSPARENT CONDUCTIVE SUBSTRATE

(75) Inventor: Annette J. Krisko, Sauk CIty, WI (US)

(73) Assignee: CARDINAL CG COMPANY, Eden Prairie, MN (US)

(21) Appl. No.: 13/112,355

(22) Filed: May 20, 2011

Related U.S. Application Data
(60) Provisional application No. 61/346,646, filed on May 20, 2010.

(51) Int. Cl. H01L 31/02; H01L 31/18; H01L 31/0224

(52) U.S. Cl. 136/256; 438/86; 257/E31.015

(57) ABSTRACT

A photovoltaic element for photovoltaic applications includes a transparent substrate having a first side and a second side. A transparent electrically conductive oxide is disposed over the first side of the transparent substrate. Similarly, a hydrophilic oxide coating is disposed over and contacts the transparent electrically conductive oxide. Finally, a removable protective coating is disposed over the hydrophilic oxide coating.

### CROSS-REFERENCE TO RELATED APPLICATIONS

This application claims the benefit of U.S. provisional application Ser. No. 61/346,646, filed May 20, 2010.

### BACKGROUND OF THE INVENTION

1. Field of the Invention

The present invention relates to transparent electrically conductive substrates for photovoltaic applications.

2. Background Art

Transparent electrically conductive substrates are used in a number of electronic applications. Examples of technologies that utilize transparent conductive substrates include photovoltaic devices, electrochromic devices, optical sensors, liquid crystal displays, and the like.

Transparent electrically conductive substrates are particularly useful in multilayered photovoltaic devices as a front contact (i.e., facing the sun) due to the inability of metal grid systems alone to effectively collect the photogenerated current. Although the current transparent electrode technology works reasonably well, there are a number of deficiencies that remain unsolved. For example, transparent conductive films are typically deposited onto transparent substrates at a different facility than the one used to deposit the photoactive layers. Therefore, the transparent electrodes are often damaged or contaminated during transport. Moreover, photovoltaic devices place unique design considerations on the transparent electrode. For example, in cadmium telluride (CdTe) based solar cells, a cadmium sulfide (CdS) layer is usually deposited over the transparent electrode. It has been found that such CdS layers tend to be quite inhomogeneous. This phenomenon is believed to be due to difficulties in nucleating the CdS onto the transparent conducting films.

Accordingly, for at least these reasons, there is a need for improved transparent electrode designs and for methods of making such electrode systems.

### SUMMARY OF THE INVENTION

The present invention solves one or more problems of the prior art by providing in at least one embodiment a photovoltaic element, and in particular, a transparent electrode. The photovoltaic element includes a transparent substrate having a first side and a second side. A transparent electrically conductive layer, and in particular, a transparent conductive oxide (TCO) is disposed over the first side of the transparent substrate. Similarly, a hydrophilic oxide coating is disposed over and contacts the transparent electrically conductive layer. Finally, a removable protective coating is optionally disposed over the hydrophilic oxide coating.

In another embodiment, a photovoltaic element with a buffer layer is provided. The photovoltaic element includes a transparent substrate having a first side and a second side. A transparent electrically conductive layer, and in particular, a transparent conductive oxide is disposed over the first side of the transparent substrate. A buffer layer is then disposed over the transparent electrically conductive layer. A hydrophilic oxide coating is disposed over and contacts the buffer layer.

In another embodiment, each of the electrodes set forth above are coated with a removable protective coating over one or both sides.

In still another embodiment, a method of forming a photovoltaic element is provided. The method comprises a step in which a transparent electrically conductive layer, and in particular a transparent conductive oxide is deposited onto the first side of the transparent substrate. A buffer layer is then optionally deposited over the transparent electrically conductive layer. A hydrophilic oxide coating is then deposited over the transparent electrically conductive layer or the buffer layer if present.

It should be understood that the detailed description and specific examples, while disclosing exemplary embodiments of the invention, are intended for purposes of illustration only and are not intended to limit the scope of the invention.

### BRIEF DESCRIPTION OF THE DRAWINGS

Exemplary embodiments of the present invention will become more fully understood from the detailed description and the accompanying drawings, wherein:

FIG. 1A provides a schematic cross section of an embodiment of a thin film photovoltaic solar cell incorporating a transparent electrically conductive electrode assembly;

FIG. 1B provides a schematic cross section of the transparent electrically conductive electrode assembly used in the photovoltaic solar cell of FIG. 1A;

FIG. 2A provides a schematic cross section of another embodiment of a thin film photovoltaic solar cell incorporating a transparent electrically conductive electrode assembly;

FIG. 2B provides a schematic section of the transparent electrically conductive electrode assembly used in the photovoltaic solar cell of FIG. 2A;

FIG. 3 provides a schematic cross section of the transparent electrically conductive electrode assembly of FIG. 1B over-coated with a protective zinc oxide layer on a single side;

FIG. 4 provides a schematic cross section of the transparent electrically conductive electrode assembly of FIG. 2B over-coated with a protective zinc oxide layer on a single side;

FIG. 5 provides a schematic cross section of the transparent electrically conductive electrode assembly of FIG. 1B over-coated with a protective zinc oxide layer on a single side;

FIG. 6 provides a schematic cross section of the transparent electrically conductive electrode assembly of FIG. 1B over-coated with a protective zinc oxide layer on both sides; and

FIG. 7 provides a schematic cross section of the transparent electrically conductive electrode assembly of FIG. 2B over-coated with a protective zinc oxide layer on both sides.

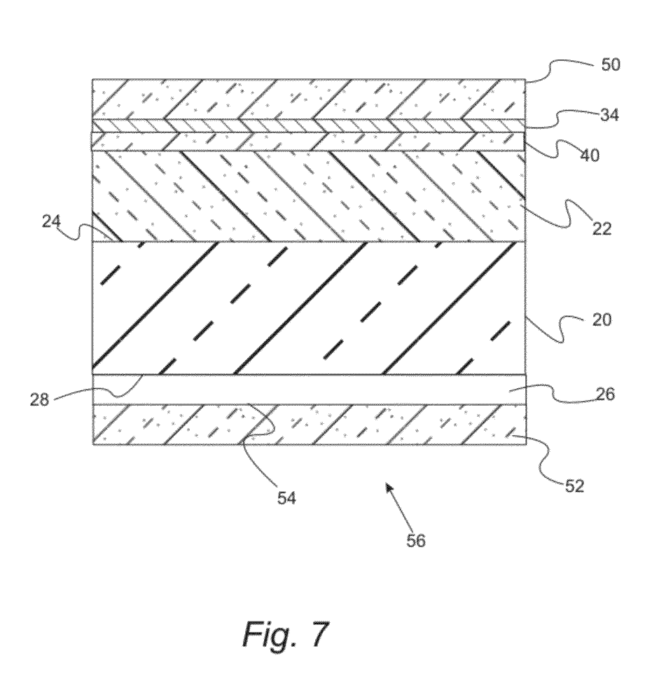

### DETAILED DESCRIPTION OF THE PREFERRED EMBODIMENT(S)

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation; and, unless expressly stated to the contrary, measurement of a property is determined by the same technique as previously or later referenced for the same property.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

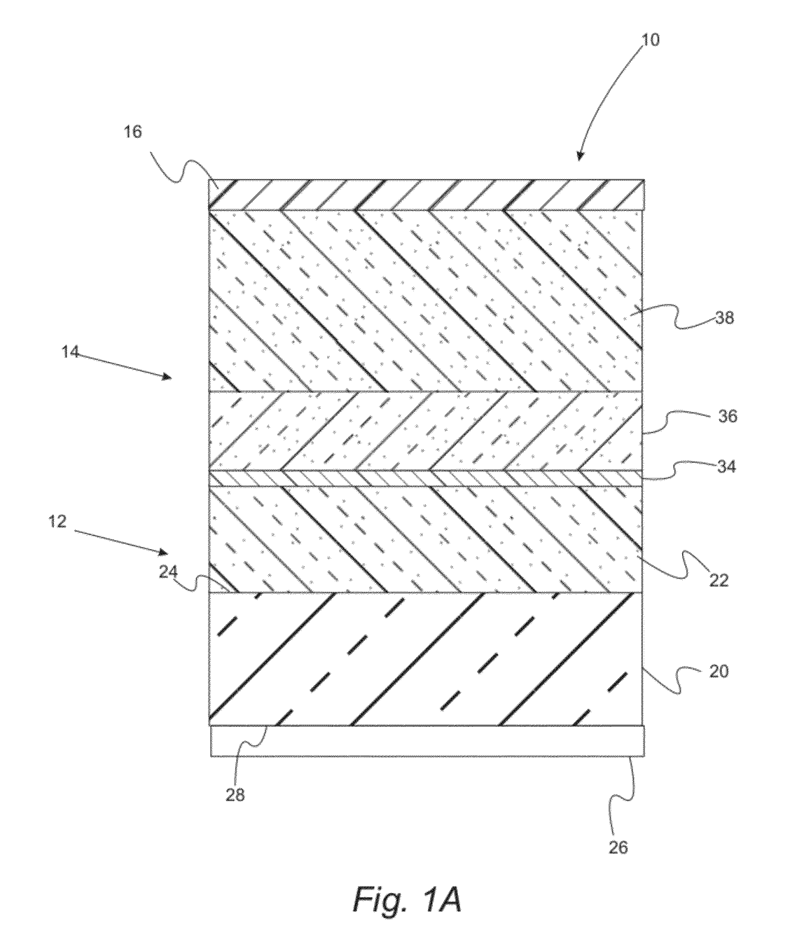

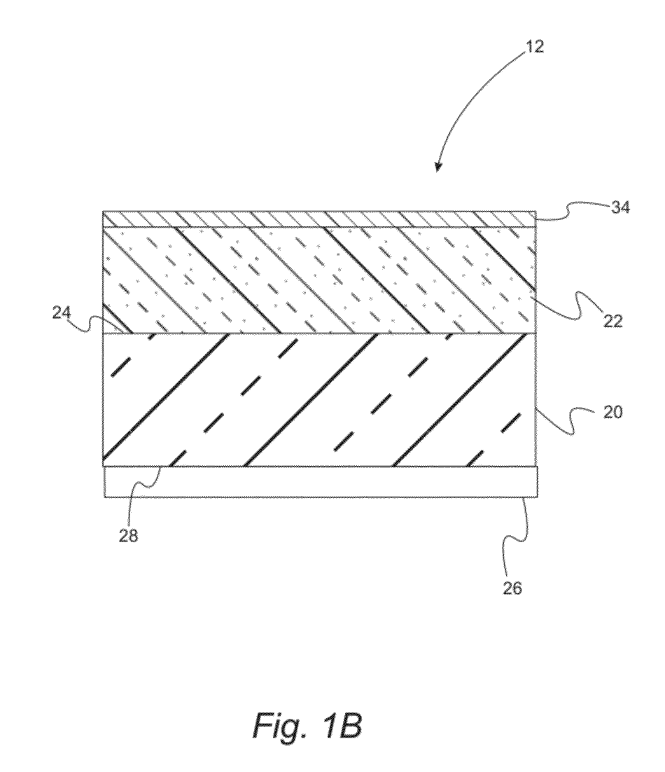

With reference to FIGS. 1A and 1B, schematic illustrations of an embodiment of a photovoltaic device incorporating a transparent electrically conductive electrode assembly are provided. FIG. 1A is a schematic cross section of the photovoltaic device. FIG. 1B is a schematic cross section of the transparent electrically conductive electrode assembly. Photovoltaic device 10 includes transparent electrode assembly 12. Disposed over transparent electrode assembly 12 is photovoltaic active multilayer component 14. Finally, conductive layer 16 is disposed over photovoltaic active multilayer component 14.

In a variation of the present embodiment, transparent electrode assembly 12 includes one or more thin film layers disposed over transparent substrate 20. In the context of the present invention, a thin film layer is a layer having a thickness from about 5 angstroms to about 10 microns. In one refinement, transparent conductive layer 22 is disposed over side 24 of transparent substrate 20. Typically, transparent conductive layer 22 is of a sufficient thickness to provide a sheet resistance from about 2 ohms-square to about 30 ohms-square. Examples of suitable materials for transparent conductive layer 22 include, but are not limited to, transparent conductive oxides such as doped zinc oxides, doped tin oxides, doped indium oxides, cadmium stannate, and the like. Zinc oxide is advantageously doped with boron, aluminum, fluorine, and combinations thereof. Tin oxide is advantageously doped with antimony, fluorine, and combinations thereof. Indium oxide is advantageously doped with tin, fluorine, or combinations thereof. Transparent conductive oxide achieves the requisite sheet resistances at thicknesses between 2000 and 10,000 angstroms. Transparent conductive layer 22 is deposited onto transparent substrate 20 by any number of thin film deposition techniques known to those skilled in the art of tin film deposition. Examples of useful techniques include, but are not limited to, sputtering, chemical vapor deposition (low pressure and atmospheric pressure), spray pyrolysis, and the like. Sputtering is found to be particularly useful because of its superior film uniformity.

In a refinement, hydrophilic layer 34 is similarly disposed over transparent conductive layer 22. Hydrophilic layer 34 improves the uniformity of any additional layers deposited over it. This advantage is believed to be due to improvements in nucleation in subsequently deposited layers from the low contact angle of hydrophilic layer 34. In some variations, hydrophilic layer 34 protects the underlying transparent conductive layer from reaction with the photovoltaic layers. In one refinement, hydrophilic layer 34 is a hydrophilic oxide. Examples of suitable hydrophilic oxides include, but are not limited to, silicon oxide, aluminum oxide, and the like. In another refinement, hydrophilic layer 34 has a thickness from 5 angstroms to 50 angstroms. In yet another refinement, hydrophilic layer 34 has a thickness from 5 angstroms to 20 angstroms. The upper thickness limit is required to ensure that the resistivity of the transparent electrode assembly is not too high. In still another refinement, hydrophilic layer 34 has a thickness from 5 angstroms to 10 angstroms. It should be appreciated that layers that are in the thickness range 5 to 50 angstroms may be discontinuous depending on the deposition process. In one variation, the thickness ranges recited herein are average thicknesses of cross sections as determined by scanning electron microscopy. In another variation, the thickness ranges recited herein are the maximum thickness of cross sections as determined by scanning electron microscopy.

Still referring to FIGS. 1A and 1B, hydrophilic layer 34 is deposited onto transparent conductive layer 22 by any number of thin film deposition techniques known to those skilled in the art of tin film deposition. Examples of useful techniques include, but are not limited to, sputtering, chemical vapor deposition (low pressure and atmospheric pressure), spray pyrolysis, and the like. Sputtering is found to be particularly useful because of its superior film uniformity.

In a further refinement of the transparent electrode of FIG. 1B, anti-reflective assembly 26 is disposed over side 28 of transparent substrate 20. Anti-reflective assembly 26 may be of either a single layer or multilayer design.

In yet another refinement of the transparent electrode of FIG. 1B, one or more layers are interposed between transparent substrate 20 and transparent conductive layer 22. In one example, transparent substrate 20 is first coated with a thin tin oxide layer (50 to 300 angstroms) and then a silicon oxide layer (100 to 500 angstroms) to form a high/low anti-reflecting film stack to increase transmission through the transparent electrically conductive assembly. In another example, substrate 20 may be coated with a silicon oxide layer (100 to 500 angstroms) to protect transparent conductive layer 22 for the effects of sodium in the glass.

The transparent electrode assembly 12 may be used in combination with virtually any photovoltaic active layers. In one particularly useful application, photovoltaic active multilayer component 14 is of a CdS/CdTe configuration. In this variation, photovoltaic active multilayer component 14 includes cadmium sulfide layer 36 and cadmium telluride layer 38. Cadmium sulfide layer 36 is disposed over hydrophilic layer 34 while cadmium telluride layer 38 is disposed over cadmium sulfide layer 36.

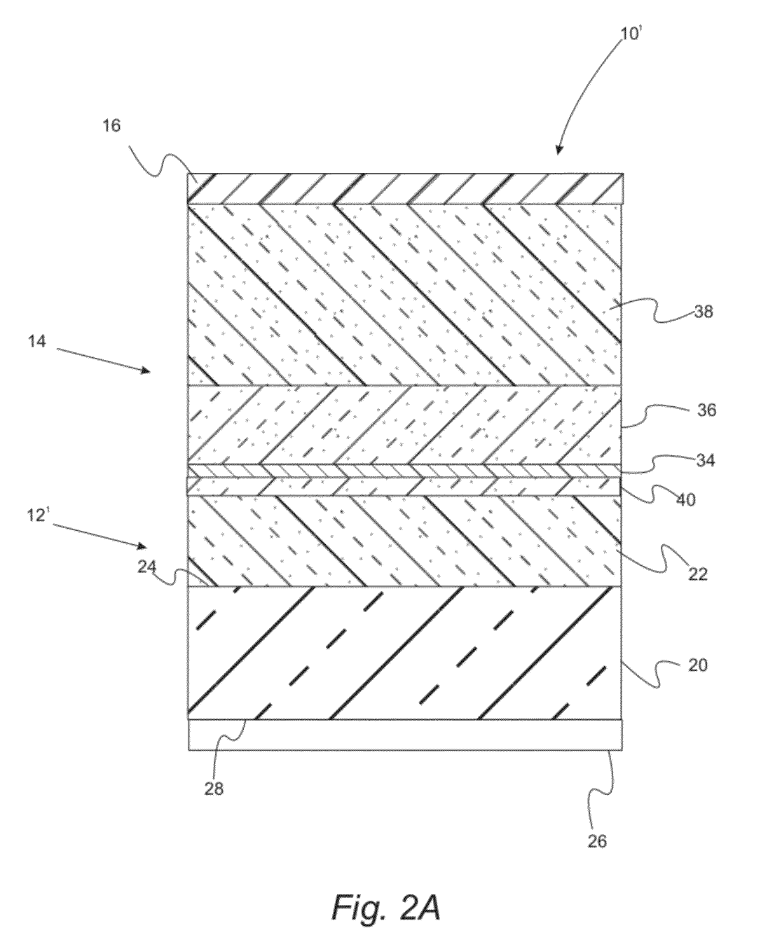

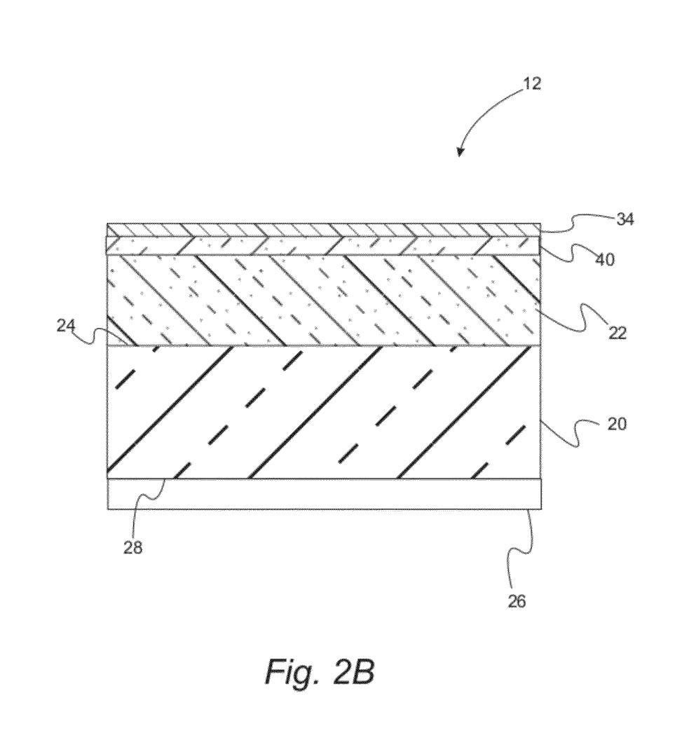

With reference to FIGS. 2A and 2B, schematic illustrations of another embodiment of a photovoltaic device incorporating an electrically conductive transparent substrate are provided. Photovoltaic device 10¹ includes transparent electrode assembly 12¹. Disposed over transparent electrode assembly 12¹ is photovoltaic active multilayer component 14. Finally, conductive layer 16 is disposed over photovoltaic active multilayer component 14.

In a variation of the present embodiment, transparent electrode assembly 12¹ includes one or more thin film layers disposed over transparent substrate 20. Transparent conductive layer 22 is disposed over side 24 of transparent substrate 20. Typically, transparent conductive layer 22 is of a sufficient thickness to provide a sheet resistance from about 2 ohms-square to about 30 ohms-square. Examples of suitable materials for transparent conductive layer 22 include, but are not limited to, transparent conducting oxides such as doped zinc oxides, doped tin oxides, doped indium oxides, cadmium stannate, and the like. Zinc oxide is advantageously doped with boron, aluminum, fluorine, and combinations thereof. Tin oxide is advantageously doped with antimony, fluorine, and combinations thereof. Indium oxide is advantageously doped with tin, fluorine, or combinations thereof. Transparent conductive layer 22 is deposited onto transparent substrate 20 by any number of thin film deposition techniques known to those skilled in the art of tin film deposition. Examples of useful techniques include, but are not limited to, sputtering, chemical vapor deposition (low pressure and atmospheric pressure), spray pyrolysis, and the like. Sputtering is found to be particularly useful because of its superior film uniformity.

In accordance with the present embodiment, buffer layer 40 is disposed over transparent conductive layer 22. Typically, buffer layer 40 is also a transparent conductive layer but is characterized by having a much higher resistance than transparent conductive layer 22. Examples of useful buffer layers include, but are not limited to, doped or undoped zinc oxides, doped or undoped tin oxides, doped or undoped indium oxides, and the like. When doped, the level of doping is typically much less than the doping of the more transparent conductive layer 22. In a variation, the thickness of buffer layer 40 is from about 100 to about 1000 angstroms. In another variation, the thickness of buffer layer 40 is from about 300 to about 700 angstroms.

Hydrophilic layer 34 is similarly disposed over buffer layer 40. Hydrophilic layer 34 improves the uniformity of any additional layers deposited over it. In some variations, hydrophilic layer 34 protects the underlying transparent conductive layer from reaction with the photovoltaic layers. In one refinement, hydrophilic layer 34 is a hydrophilic oxide. Examples of suitable hydrophilic oxides include, but are not limited to, silicon oxide, aluminum oxide, and the like. In another refinement, hydrophilic layer 34 has a thickness from 5 angstroms to 50 angstroms. In yet another refinement, hydrophilic layer 34 has a thickness from 5 angstroms to 20 angstroms. It should be appreciated that layers that are in the thickness range 5 to 50 angstroms are typically discontinuous. In one variation, the thickness ranges recited herein are average thicknesses of cross sections as determined by scanning electron microscopy. In another variation, the thickness ranges recited herein are the maximum thickness of cross sections as determined by scanning electron microscopy.

Hydrophilic layer 34 is deposited onto buffer layer 40 by any number of thin film deposition techniques known to those skilled in the art of tin film deposition. Examples of useful techniques include, but are not limited to, sputtering, chemical vapor deposition (low pressure and atmospheric pressure), spray pyrolysis, and the like. Sputtering is found to be particularly useful because of its superior film uniformity.

In a further refinement of the transparent electrode of FIG. 2B, anti-reflective assembly 26 is disposed over side 28 of transparent substrate 20. Anti-reflective assembly 26 may be of either a single layer or multilayer design.

In yet another refinement of the transparent electrode of FIG. 2B, one or more layers are interposed between transparent substrate 20 and transparent conductive layer 22. For example, substrate 20 may be coated with a silicon oxide layer (100 to 500 angstroms) to protect transparent conductive layer 22 for the effects of sodium in the glass. In another example, transparent substrate 20 is first coated with a thin tin oxide layer (50 to 300 angstroms) and then a silicon oxide layer (100 to 500 angstroms). This latter example acts to induce haze in the transparent electrode.

As set forth above in connection with the description of FIGS. 1A and 1B, the transparent electrode assembly 12¹ may be used in combination with virtually any photovoltaic active layers. In one particularly useful application, photovoltaic active multilayer component 14 is of a CdS/CdTe configuration.

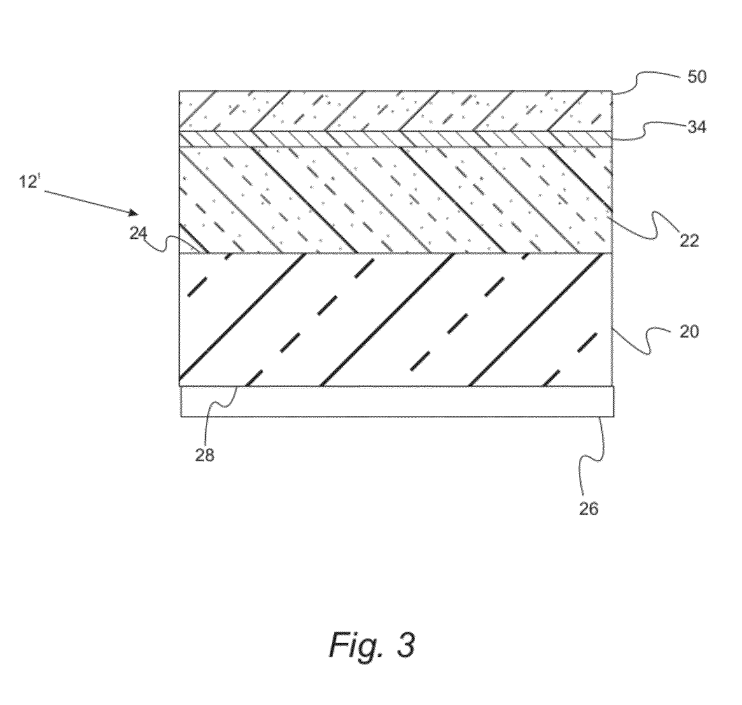

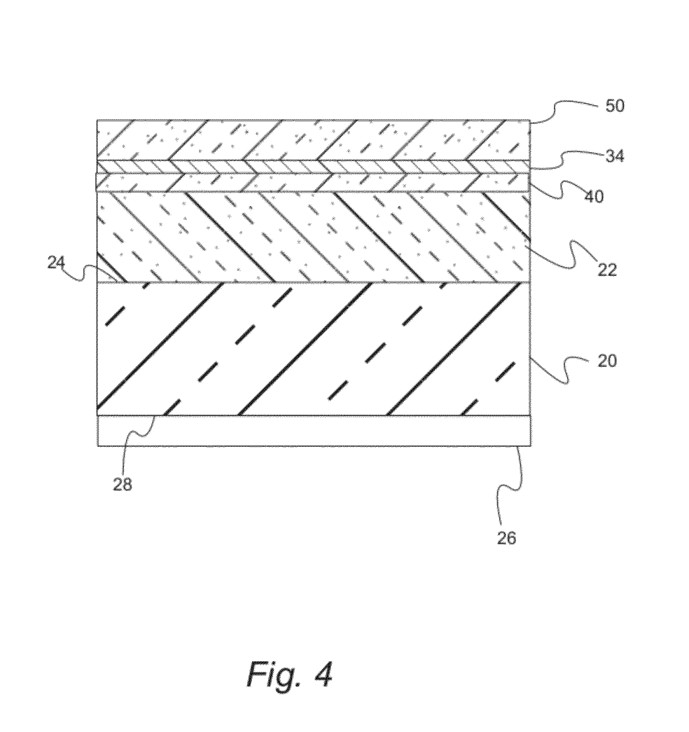

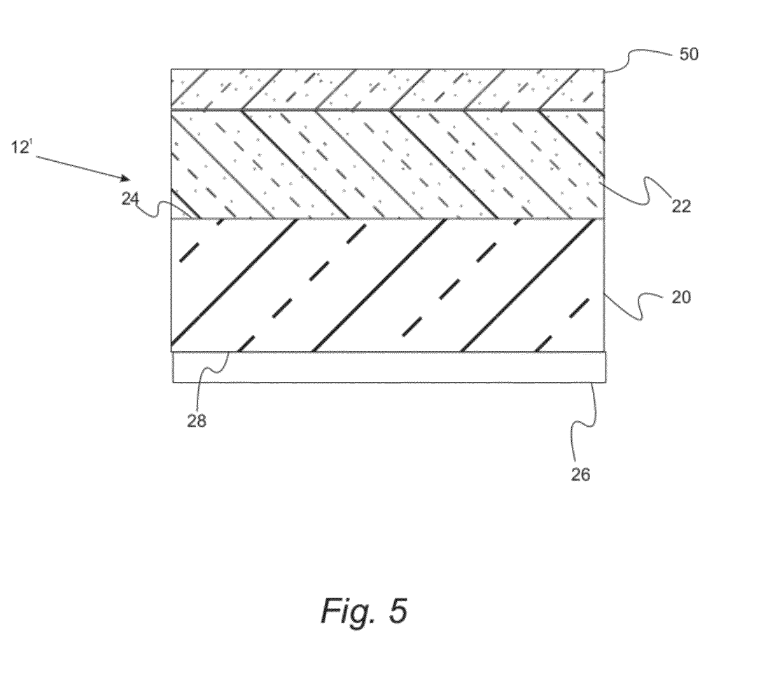

With reference to FIGS. 3, 4, and 5, schematic cross sections of the transparent electrically conductive electrode assemblies of FIGS. 1B and 2B over-coated with a protective zinc oxide layer are provided. In this variation, zinc oxide layer 50 is disposed over hydrophilic layer 34 (FIGS. 3 and 4) or directly over transparent conductive layer 22 (FIG. 5). Zinc oxide layer 50 provides protection of the electrode after fabrications of transparent electrode assembly 12 or of transparent electrode assembly 12¹. Advantageously, zinc oxide layer 50 is removed prior to depositions of photovoltaic active multilayer component 14. Zinc oxide layer 50 is easily removed by a weakly acidic aqueous solution or a weak acid such as acetic acid. Such acidic solutions also provide hydration of the silicon oxide surface which might be useful for maintaining hydrophilicity. Zinc oxide layer 50 ensures that the low contact angle of hydrophilic layer 34 is maintained until additional layers are deposited over the electrically conductive electrode assembly as dirt and other spoilage tend to increase the contact angle. After removal of zinc oxide layer 50 by the acid treatment a pristine surface with a low contact angle is exposed.

Still referring to FIGS. 3, 4, and 5, zinc oxide layer 50 is deposited over hydrophilic layer 34 or over transparent conductive layer 22 by any number of thin film deposition techniques known to those skilled in the art of tin film deposition. Examples of useful techniques include, but are not limited to, sputtering, chemical vapor deposition (low pressure and atmospheric pressure), spray pyrolysis, and the like. Sputtering is found to be particularly useful because of its superior film uniformity. Zinc oxide layer 50 may be either undoped or doped as set forth above. In each of the variations set forth in FIGS. 3 and 4, the thickness of zinc oxide layer 50 is from 20 to 300 angstroms. In some other refinements, the thickness of zinc oxide layer 50 is from 40 to 100 angstroms.

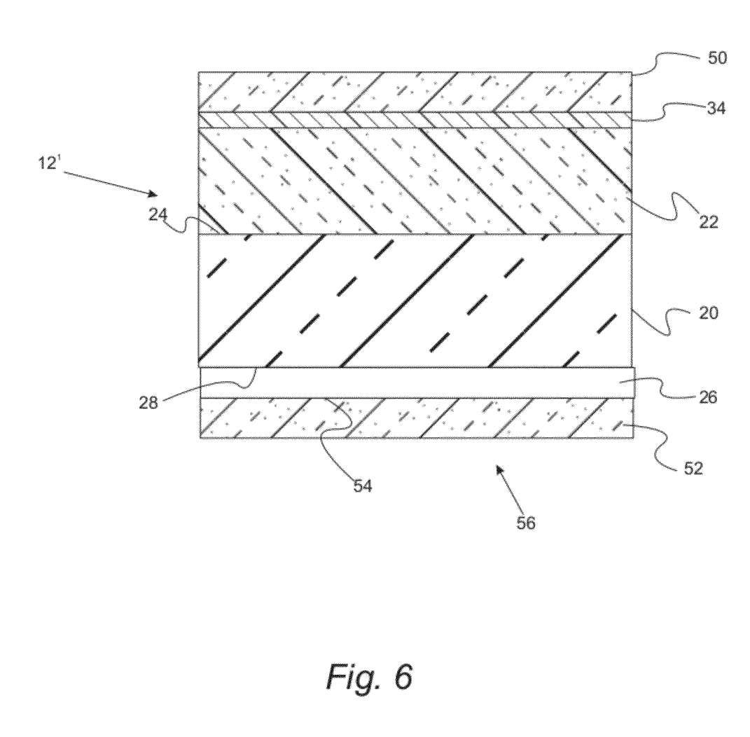

With reference to FIGS. 5 and 6, schematic cross sections of the transparent electrically conductive electrode assemblies of FIGS. 1B and 2B over-coated with a protective zinc oxide layer on two sides are provided. In this variation, zinc oxide layer 50 is disposed over optional hydrophilic layer 34 while zinc oxide layer 52 is disposed over side 54 of transparent substrate 20. Optional antireflective assembly 26 may be interposed between transparent substrate 20 and zinc oxide layer 52. Zinc oxide layer 50 provides protection of the electrode after fabrication of transparent electrode assembly 12 or of transparent electrode assembly 12¹. Advantageously, zinc oxide layer 50 is removed prior to depositions of photovoltaic active multilayer component 14. In a variation, zinc oxide layer 52 is removed after photovoltaic active multilayer component 14 has been deposited. In this regard, zinc oxide layer 52 protects side 56 of the transparent electrode from contamination during formation of the device. Zinc oxide layers 50, 52 are easily removed as set forth above by a weakly acidic aqueous solution or a weak acid such as acetic acid. In each of the variations set forth in FIGS. 5 and 6, the thickness of zinc oxide layers 50, 52 are each independently from 20 to 300 angstroms. In some other refinements, the thickness of zinc oxide layers 50, 52 are each independently from 40 to 100 angstroms. In a further refinement, the thickness of zinc oxide layer 52 is greater than the thickness of zinc oxide layer 50 in order to provide greater protection to side 56 of the transparent electrode.

The following example illustrates the various embodiments of the present invention. Those skilled in the art will recognize many variations that are within the spirit of the present invention and scope of the claims.

### 1. Preparation of a Zinc Oxide based Transparent Electrode

A mid-iron float glass substrate is coated with a tin oxide film as follows. The mid-iron float glass is transported through a tin oxide sputter coating position at a speed of about 209 inches per minute (ipm). The sputter coating position has an associated tin target. A gaseous mixture of about 75 volume percent argon and 25 volume percent oxygen is provided at the tin oxide coating position with the argon flow being about 1254 sccm and the oxygen flow being about 416 sccm. The pressure at the sputtering position is about 6 mT. The tin target is sputtered at a bias voltage of about 475 volts, a current of about 60 amps, and a power of about 25 KW. The resulting tin oxide film has a thickness of about 150 angstroms.

A 300 angstrom silicon oxide film is deposited over the tin oxide film by transporting the coated mid-iron float glass at a speed of about 166 ipm through three silicon oxide sputter coating positions each having an associated silicon target (silicon oxide sputtering position 1, 2, and 3). A gaseous mixture of about 71 volume percent argon and 29 volume percent oxygen is provided at each silicon oxide sputtering position. The argon flow at each silicon oxide sputtering position is 1186 sccm. The oxygen flows to silicon oxide sputtering positions 1, 2, and 3 are about 174 sccm, 133 sccm, and 183 sccm, respectively. Each silicon oxide sputtering position has a pressure of about 5 mT. The silicon target is sputtered at a bias voltage of about 445 volts, a current of about 105 amps, and a power of about 37.5 KW.

The mid-iron float glass substrate is next coated with an aluminum-doped zinc oxide film having a thickness of about 6000 angstrom. The mid-iron float glass substrate is transported through two zinc oxide sputtering positions each having a zinc oxide target containing about 2% aluminum. The transport speed through the zinc oxide positions is about 25 ipm. In order to achieve the required thickness, the substrate is passed two times through the two zinc oxide sputtering positions. The zinc oxide sputtering positions are operated with about 100% argon at a pressure of about 7.2 mT. The zinc targets associated with each zinc oxide sputtering position are sputtered at a bias voltage of about 480 volts, a current of about 74 amps, and a power of about 30 KW.

The mid-iron float glass is next coated with a tin oxide film of about 500 angstroms. The mid-iron float glass substrate is transported through a tin oxide sputter coating position at a speed of about 63 ipm. The tin oxide sputter coating zone is associated with a tin target. A gaseous mixture of about 75 volume percent argon and 25 volume percent oxygen is provided to the reaction chamber with the argon flow being about 1254 sccm and the oxygen flow being about 416 sccm. The pressure at the tin oxide sputtering position is about 6 mT. The tin target is sputtered at a bias voltage of about 475 volts, a current of about 60 amps, and a power of about 25 KW.

A thin silicon oxide layer is then deposited over the substrate. The coated mid-iron float glass is passed at a speed of about 534 ipm through a silicon oxide sputtering position associated with a silicon target. A gaseous mixture of about 71 volume percent argon and 29 volume percent oxygen is provided to the silicon oxide sputtering position. The silicon oxide sputtering zone has a pressure of about 5 mT. The silicon target is sputtered at a bias voltage of about 445 volts, a current of about 103 amps, and a power of about 37.5 KW. The thickness of the silicon oxide layer is about 30 angstroms.

The mid-iron float glass is next coated with a protective zinc oxide layer of about 40 angstroms. The mid-iron float glass substrate is transported though a zinc oxide sputtering position associated with a zinc oxide target containing about 2% aluminum. The transport speed through the zinc oxide position is about 242 ipm. The zinc oxide sputtering position is operated with about 100% argon at a pressure of about 7.2 mT. The zinc targets associated with each zinc oxide sputtering position are sputtered at a bias voltage of about 391 volts, a current of about 27.4 amps, and a power of about 10 KW.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A photovoltaic element for photovoltaic applications, the photovoltaic element comprising:
a transparent substrate having a first side and a second side;
a transparent electrically conductive layer disposed over the first side of the transparent substrate; and
a hydrophilic oxide coating disposed over and contacting the transparent electrically conductive layer.

2. The photovoltaic element of claim 1 further comprising a cadmium sulfide layer disposed over and contacting the hydrophilic oxide coating.

3. The photovoltaic element of claim 1 further comprising a removable protective coating disposed over the hydrophilic oxide coating.

4. The photovoltaic element of claim 1 wherein the transparent conductive layer is of a sufficient thickness to provide a sheet resistance from about 2 ohms-square to about 30 ohms-square.

5. The photovoltaic element of claim 1 wherein the transparent conductive layer comprises a transparent conductive oxide selected from the group consisting of doped zinc oxides, doped tin oxides, doped indium oxides, cadmium stannate, and combinations thereof.

6. The photovoltaic element of claim 3 wherein the hydrophilic oxide is selected from the group consisting of silicon oxide, aluminum oxide, and combinations thereof.

7. The photovoltaic element of claim 1 wherein the hydrophilic oxide layer has a thickness from 5 angstroms to 50 angstroms.

8. The photovoltaic element of claim 1 wherein an anti-reflective assembly is disposed over the second side of the transparent substrate.

9. The photovoltaic element of claim 1 wherein one or more layers are interposed between the transparent substrate and the transparent conductive layer.

10. The photovoltaic element of claim 1 wherein a 50 to 300 angstrom tin oxide film is interposed between the transparent electrically conductive layer and the transparent substrate.

11. The photovoltaic element of claim 1 wherein a 100 to 500 angstroms silicon oxide layer is interposed between the tin oxide film and the transparent electrically conductive layer.

12. A photovoltaic element for photovoltaic applications, the photovoltaic element comprising:
a transparent substrate having a first side and a second side;
a transparent electrically conductive layer disposed over the first side of the transparent substrate;
a buffer layer disposed over the transparent electrically conductive layer; and
a hydrophilic oxide coating disposed over and contacting the buffer layer.

13. The photovoltaic element of claim 12 further comprising a cadmium sulfide layer disposed over and contacting the hydrophilic oxide coating.

14. The photovoltaic element of claim 12 wherein the buffer layer comprises a transparent conducting oxide having a higher resistivity than the transparent electrically conductive oxide.

15. The photovoltaic element of claim 14 wherein the buffer layer comprises a component selected from the group consisting of doped or undoped zinc oxides, doped or undoped tin oxides, doped or undoped indium oxides, and combinations thereof.

16. The photovoltaic element of claim 12 wherein the buffer layer has a thickness from about 100 to about 1000 angstroms.

17. The photovoltaic element of claim 12 further comprising a removable protective coating disposed over the hydrophilic oxide coating.

18. The photovoltaic element of claim 12 wherein the transparent conductive layer is of a sufficient thickness to provide a sheet resistance from about 2 ohms-square to about 30 ohms-square.

19. The photovoltaic element of claim 12 wherein the transparent conductive layer comprises a transparent conductive oxide selected from the group consisting of doped zinc oxides, doped tin oxides, doped indium oxides, cadmium stannate, and combinations thereof.

20. The photovoltaic element of claim 12 wherein the hydrophilic oxide is selected from the group consisting of silicon oxide, aluminum oxide, and combinations thereof.

21. The photovoltaic element of claim 12 wherein the hydrophilic oxide layer has a thickness from 5 angstroms to 50 angstroms.

22. A method for coating a transparent substrate having a first side and a second side, the method comprising:
depositing a transparent electrically conductive layer onto the first side of the transparent substrate;
depositing a hydrophilic oxide coating onto the transparent electrically conductive layer; and
depositing a cadmium sulfide layer onto the hydrophilic oxide coating
